(19) United States
(12) Patent Application Publication
(10) Pub. No.: US 2004/0211979 A1
(43) Pub. Date: Oct. 28, 2004

(54) Circuit board and method for manufacturing the circuit board

(75) Inventors: Kazuyoshi Shioiri, Kyouto-shi (JP); Tetsuya Yoshida, Tokyo (JP); Yuusuke Kawahara, Tokyo (JP); Kazuyoshi Ichikawa, Tokyo (JP)

Correspondence Address: MUSERLIAN AND LUCAS AND MERCANTI, LLP, 475 PARK AVENUE SOUTH, NEW YORK, NY, 10016, US

(73) Assignee: Konica Minolta Holdings, Inc., Tokyo (JP)

(21) Appl. No.: 10/824,080

(22) Filed: Apr. 14, 2004

(30) Foreign Application Priority Data
Apr. 24, 2003 (JP) 2003-119970
Apr. 24, 2003 (JP) 2003-120113

(51) Int. Cl. H01L 31/0328

(52) U.S. Cl. 257/199

(57) ABSTRACT

A circuit board includes a base material, a conductive pattern which is formed on the base material, and a resin layer which is formed on the conductive pattern by a photocurable resin.

### BACKGROUND OF THE INVENTION

1. Field of the Invention

The present invention relates to a circuit board on the surface of which conductive pattern is formed, and a method for manufacturing the circuit board.

2. Description of the Related Art

As a technology for manufacturing a circuit board, the technology that droplet pattern made up of droplets of conductive pattern forming composition is formed on a surface of a base board by ink-jet method, and the droplet pattern is heated to be a conductive pattern, has been known (for example, see Tokukai-2002-134878A).

In the conductive pattern forming composition used in the above technology, conductive fine particles formed in a minute scale are contained in a dispersed state, and the conductive fine particles form a conductive pattern when it is heated and fused one another on a surface of a base material (for example, see Tokukaihei-11-80647A).

However, when conductive pattern is formed with micro conductive fine particles on a surface of a base material, it has been a problematic that conductivity of the conductive pattern is easily degraded by the oxidation thereof.

### SUMMARY OF THE INVENTION

The object of the invention is to provide a circuit board where conductive pattern is prevented from oxidation and a method for manufacturing the circuit board.

According to the first aspect of the invention, a circuit board of the invention comprises a base material, a conductive pattern which is formed on the base material, and a resin layer which is formed on the conductive pattern by a photocurable resin.

Since the resin layer is formed on the conductive pattern, the conductive pattern can be defiladed from oxygen, that is, the conductive pattern can be prevented from oxidation.

In the circuit board of the invention, the photocurable resin may comprise a photo polymerization initiator and a photocurable acrylic type monomer or a photocurable acrylic oligomer as a main component.

Since the photocurable resin comprises a photo polymerization initiator and a photocurable acrylic type monomer or acrylic oligomer as a main component, it can be certainly cured by light. Therefore, it becomes possible to form the resin layer on the conductive pattern without oxidizing the conductive pattern.

In the circuit board of the invention, a line width of the conductive pattern is preferably 20 μm or less.

Since line width of the conductive pattern is 20 μm or less, it becomes possible to prevent oxidation of the fine conductive pattern.

The circuit board of the invention may further comprise a magnetic shielding layer both/either between the base material and the conductive pattern and/or on a surface side of the base material, which is an opposite side of a side where the conductive pattern is formed.

Since the circuit board of the invention comprises a magnetic shielding layer provided at least one of between the base material and the conductive pattern, and on a surface plane where the conductive pattern is not formed in the base material, electromagnetic shielding property of the circuit board itself also can be enhanced.

According to the second aspect of the invention,

A manufacturing method of a circuit board comprises;

drawing a droplet pattern with droplets of a conductive pattern forming composition on a surface of a base material,

heating the drawn droplet pattern so as to convert the droplet pattern into a conductive pattern,

coating a photocurable resin onto the conductive pattern after the heating, and

irradiating light to cure the coated photocurable resin after the coating.

Since the resin layer is formed on the conductive pattern by the drawing and the irradiation, the conductive pattern can be defiladed from oxygen, that is, it becomes possible to prevent the conductive pattern from oxidation.

In the method described above, the drawing may comprise drawing the droplet pattern by jetting droplets of the conductive pattern forming composition in an ink-jet method.

Since the droplet pattern is drawn by ink-jet method, it becomes possible to draw fine droplet pattern easily.

In the method described above, the drawing may comprise jetting the conductive pattern forming composition from a nozzle having a nozzle diameter of 0.1 μm to 10 μm.

Since the conductive pattern forming composition is jetted from a nozzle having a nozzle diameter of 0.1 μm to 10 μm, fine droplet pattern can be formed.

In the method described above, the drawing may comprise drawing the droplet pattern having line width of 20 μm or less.

Since the droplet pattern having line width of 20 μm or less is drawn, fine droplet pattern can be formed.

In the method described above, the conductive pattern forming composition may comprise conductive fine particles made up of at least one kind of metal and a dispersant which disperses the conductive pattern fine particles, and wherein the dispersant comprises a polymer in which a main chain comprises tertiary amine type monomer and a side chain comprises polyether type anionic monomer.

Since the dispersant comprises a polymer in which a main chain comprises tertiary amine type monomer and a side chain comprises polyether type anionic monomer, the conductive fine particles is dispersed without aggregation in the conductive pattern forming composition in which the dispersant works as a protective colloid. Therefore, since fine conductive pattern can be formed by the micro conductive fine particles, it becomes possible to increase implementing density of the conductive pattern in the base material. Further since the conductive fine particles can be minimized in particle size in the conductive pattern forming composition, it becomes possible that heating at comparatively low temperature can provide conductivity to the droplet pattern formed on the base material by droplets of the conductive pattern forming composition by.

As the metal, copper and rare metals are preferable. The rare metals include gold, silver, ruthenium, rhodium, palladium, osmium and iridium.

In the method described above, a sol-gel solution for forming a magnetic shielding layer is preferably coated onto at least one surface of the base material and is cured to be the magnetic shielding layer, and subsequently the drawing is performed onto at least one surface of the magnetic shielding layer side and the base material side.

Further in the method described above, sol-gel solution for forming a magnetic shielding layer is coated onto a reverse side of a surface where the conductive pattern is formed by the heating in the base material, and cured to form the magnetic shielding layer.

Since the magnetic shielding layer is provided at least one of between the base material 3 and the conductive pattern, and on a surface plane where the conductive pattern is not formed, it becomes possible that electromagnetic shielding property of the base board itself is enhanced.

### BRIEF DESCRIPTION OF THE DRAWINGS

The present invention will become fully understood by the detailed description and accompanied drawings stated hereinbelow. However, those are simply a explanation and not intended to limit the scope of the invention, and wherein;

FIG. 1 is a longitudinal sectional view of the circuit board of the first embodiment, and FIG. 2 is a longitudinal sectional view of the circuit board of the second embodiment.

### PREFERRED EMBODIMENT OF THE INVENTION

Hereinafter, the embodiments of the present invention will be explained. However it is not intended that following description of the embodiments in the invention limits the technical scope of the limitations and meaning of the terms which are listed in the claims of the invention. Furthermore, the assertive explanations stated in the embodiments of the present invention is intended to show the best mode of the embodiment, thus do not limit the meaning of the terms and the technical scope of the invention.

### First Embodiment

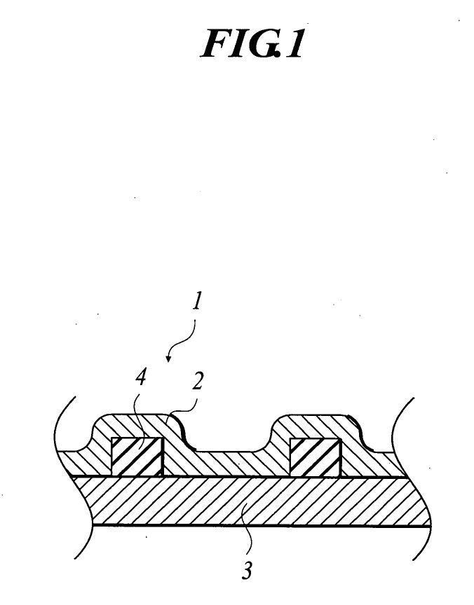

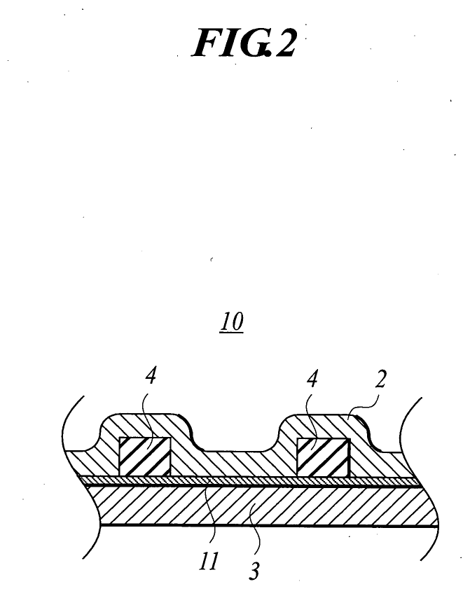

Hereinafter, the first embodiment of the present invention is explained with referring to FIG. 1. FIG. 1 is a sectional view showing a circuit board of the present invention. As shown in FIG. 1, circuit board 1 comprises a film-like base material 3, and the surface thereof is covered with a resin layer 2 for providing protection against oxidation.

The resin layer 2 comprises a photo polymerization initiator and photocurable resin containing photo polymerizable acrylic monomer or acrylic oligomer as a main component.

The photo polymerization initiator is a carbonyl compound or a sulfur compound. The carbonyl compound includes acetophenone, ditrichloroacetophenone, trichloroacetophenone, benzophenone, Michler's ketone, benzil, benzoin, etc. The sulfur compound includes tetramethylthiraum monosulfide, thioxanthone, tetramethylthiraumsulfide, azobisiso butyronitrile, benzoilperoxide, 2,2-diethoxyacetophenone, 4-dialkylazoacetophenone, etc.

As the acrylic system monomer, monofunctional monomer, bifunctional monomer and multifunctional monomer are available.

The monofunctional monomer includes 2-hydroxyethylacrylate, 2-ethylhexylacrylate, 2-hydroxypropylacrylate, tetrahydroxyfulfuralacrylate, etc.

The bifunctional monomer includes 1,3-butadioldiacrylate, 1,4-butadioldiacrylate, 1,6-hexandioldiacrylate, diethyleneglycoldiacrylate, neopentylglycoldiacrylate, polyethyleneglycol 400 diacrylate, hydroxypivalinate neopentylglycoldiacrylate, tripropyleneglycoldiacrylate, etc. The multifunctional monomer includes trimethylolpropanetriacrylate, pentaerythritoltriacrylate, dipentaerythritolhexacrylate, etc.

As the functional acrylic system oligomer, oligomer made up of above acrylic system monomer and photo polymerizable prepolymer, etc. are available. As the photo polymerizable prepolymer, available are compounds classified by the structure of molecule which constitutes the framework as polyesteracrylate, epoxyacrylate, polyurethaneacrylate, polyetheracrylate, polyolacrylate, etc. In particular, polyesteracrylate, epoxyacrylate polyurethaneacrylate, etc are preferable.

The above photocurable resin preferably contains a sensitizer which enhances the sensitivity for light. The sesitizer includes n-butylamine, triethylamine, triethylenetetramine, tri-n-butylphosphine, etc.

A conductive pattern 4 is provided between the above resin layer 2 and the base material 3. The conductive pattern 4 is formed by fusion-boning conductive fine particles made of at least one kind of metal, and has line width of 20 μm or less. In the embodiment of the invention, the conductive fine particles are made of copper.

For more details, the conductive pattern 4 is formed by curing a droplet pattern formed by droplets of conductive pattern forming composition.

The conductive pattern forming composition is explained. Conductive pattern forming composition comprises conductive fine particles and a dispersant in a dispersing medium.

Primary component of the dispersant is water-insoluble organic solvent, concretely MEK (methylethylketone), MIBK (methylisobutylketone), ethyl acetate, butyl acetate, toluene, xylene and the like.

The conductive fine particles are made of at least one kind of metal, and is made of copper in the present embodiment. Mean particle size of the conductive fine particles is 0.1 nm or more and 20 nm or less.

The dispersant is a oligomer having a comb-like shape in which a plurality of side chains are bonded with a main chain in a manner of such as teeth of a comb, and is made of a plurality kinds of monomers which are polymerized with radicals by solution polymerization and the like to be a oligomer. Weight average molecular weight of the dispersant is 3000 to 100000.

For more detail, the dispersant is a graft polymer in which some monomer units constituting main chain have monomers of different kind arranged to be side chains, and is also a block polymer in which plural kinds of monomers are polymerized respectively with the monomer of same kind in a row.

The main chain of the dispersant contains nitrogen containing nitrogenous tertiary amin type monomer as a copolymer component, such as dimethylaminometyl (meth) acrylate, dietylaminoethyl (meth)acrylate, etc. Therefore the dipersant holds conductive fine particles stably, or keep conducitive fine particle in dispersed state, by donating an electron from nitrogen atom derived from tertiary amin type monomer.

The main chain of the dispersant preferably contains (meth)acrylic acid and the derivatives thereof in addintion to avobe-described nitrogenous tertiary amin type monomer. In this case, monomers are certain to be polymerized with radicals.

Further, the main chain of the dispersant preferably contains long-chain alkyl group such as stearyl, and stylene. In this case, conductive fine particles are certain to be dispersed by the dispersant in organosol system. The long-chain alkyl includes alkyl (meth)acrylate, 2-ethylhexyl (meth)acrylate, lauryl(meth)acrylate, stearyl(meth)acrylate, etc.

Further, the main chain of the dispersant preferably contains reactive monomers for conductive fine particles, such as glycidyl(meth)acrylate, primary amine derivative of glycidyl(meth)acrylate, polyethyleneimine derivative of glycidyl(meth) actylate, polyethyleneimine additive of poly(meth)acrylate, 2-hydroxyethyl(meth)acrylate, 2-hydroxypropyl(meth)acrylate and the like. In the case, the dispersant effectively adheres to conductive fine particles, and can disperse the conductive fine particles.

The side chain of the dispersant contains polyether type anionic monomer. Concretely, the side chain of the dispersant contains hydrophilic polyethyleneoxide and either hydrophobic polypropyleneoxide or polybutyleneoxide.

The dispersant perform its dispersing effect validly with these side chain components. Since the dispersant contains both hydrophilic and hydrophobic side chains as described above, it forms micro domain structure in a dispersing medium. Further since the number of moles of ethyleneoxide or propyleneoxide to be added can be controlled, it is possible to form monomers having superior effect of dispersing conductive fine particles, it is possible to obtain the monomer having superior features of effect to prevent conductive fine particles from aggregating, stability against variance of temperature and pH, and affinity with a dispersing medium. Further, the dispersant can improve dispersibility of conductive fine particles as well as stabilize the system by adding the molecule chains having high flexibility as side chain component, for the dispersant forms an absorption layer by covering the surface of a conductive fine particle with the molecular chain thereof. Further, the dispersant is made to be capable of changing a phase of the mixed dispersing medium of organic dispersing medium and aqueous dispersing medium, from homogeneous phase of organic dispersing medium-aqueous dispersing medium or microemulsion into perfectly separated into two phases in a manufacture of the conductive pattern forming composition.

Hereinafter, method for manufacturing a conductive pattern forming component is explained.

Isopropylalcohol as a medium, the above-described monomer components as dispersant and azoisobutylonitlile as polymerization initiator are charged into a flask in a warm bath, and solution polymerization is performed. Thus, a plurality of monomers are polymerized with radicals and the dispersant is synthesized.

Subsequently, metal compound of such as copper and the above dispersant are dissolved into an acid aqueous dispersing medium. The dispersant has high solubility to an acid aqueous medium, since it has tertiary amino group. The copper compound includes copper formate, copper acetate, copper naphthenate, copper octylate, copper acetylacetate, copper chloride, copper sulfate, copper nitrate, etc. Among them, low-cost copper sulfate or copper nitrate are preferably used.

Next, conductive fine particles are formed by reducing copper ion in the aqueous dispersing medium phase (reduction process). Concretely, organic amine such as primary amine, secondary amine or the like is added to the aqueous dispersing medium and stirred. The copper ion is reduced to be deposited to the aqueous dispersing medium phase. Here, since the dispersant is in the aqueous dispersing medium phase, deposited conductive fine particles are stably dispersed in the aqueous dispersing medium phase where the dispersant works as protective colloid. The particle size of the conductive fine particles bocomes 0.1 nm or more and 20 nm or less. Further, organic amin compound is used as reducing agent in the reduction process, so that the copper ion is reduced in comparatively mild reductive condition. Therefore, variation in particle size of deposited conductive fine particles is small. As for the organic amine to be added to the aqueous dispersing medium, preferable are alkanolamines such as methylaminoethanol, ethanol amine, propanol amine, diethanol amine, etc., and more preferable are polyethyleneimine. When polyethyleneimine is used, it can make the deposited conductive fine particles dispersed as well as it reduces the copper ion. Polyethyleneimine may be contained in a polymer as a side chain. Concretely, it is preferable to be contained as a side chain in a graft polymer whose main chain component is methyl(meth)acrylate.

Next, the aqueous dispersing medium where the conductive fine particles are dispersed is contacted with the organic dispersing medium where the above water insoluble organic solvent is a main component, so that the conductive fine particles are transferred from the above aqueous dispersing phase to organic dispersing phase by phase-transfer (phase-transfer process). Concretely, after the aqueous dispersing medium is contacted with the organic dispersing medium, the aqueous dispersing medium phase is alkalified by adding a compound such as amine, and aqueous dispersing medium and organic dispersing medium are heated at 50 to 90° C. Thus, the aqueous dispersing medium and the organic dispersing medium are separated into-two phases. Simultaneously, since degree of hydration in the dispersant, which derives from a hydrogen bond of oxygen atom and hydrogen atom of polyether part, is reduced and water solubility is remarkably decreased, water solubility of the portion originated from polyalkyleneoxide(meth)acrylate derivative in the dispersant is decreased, so that the dispersant is transferred to the organic dispersing medium phase by phase-transfer. The conductive fine particles are phase-transferred by salting-out effect of organic salt or inorganic salt which are formed by copper ion when a compound such as amine is added. As a result, being different from the state in the aqueous dispersing medium phase, the conductive fine particles become to be shielded from oxygen, that is, is in a state hardly oxidized. The conductive fine particles are kept dispersed stably in the organic dispersing medium thanks to dispersing effect of the dispersant and micro Brownian motion.

In the phase-transfer process, ultrasonic mixer is preferably used in order to mix the aqueous dispersing medium with the organic dispersing medium evenly. Thus, the aqueous dispersing medium and the organic dispersing medium form a homogenous phase or microemulsion. Here, the particle size of the microemulsion is preferably 30 nm or less, more preferably 10 nm or less.

Subsequently, the organic dispersing medium phase which has been separated as described above from the aqueous dispersing medium phase is collected and washed with purified water (purification process). By this process, since the aqueous components, concretely amine compound which has been used as a reducing agent, a part of dispersant and neutralized salt is removed, so that it becomes possible that the conductive fine particles are certainly fused with one another. The amount of the dispersant left in the organic dispersing medium after purification process is preferably 20 weight % or less based on the weight of copper. When the amount left is in the above range, since the conductive fine particles in the organic dispersing medium can contact with one another, it is possible to form a conductive pattern 4.

Subsequently the organic dispersing medium is evaporated and exsiccated.

The exsiccated organic dispersing medium is mixed with resin component and curing agent, and the mixture is extruded to be the conductive pattern forming composition.

Next, a manufacturing method for manufacturing the circuit board 1 of the invention using the conductive pattern forming composition manufactured as described above is explained.

A droplet pattern made up of droplets of conductive pattern forming composition is drawn on at least one side of the base material 3 to be a lattice shape of predetermined shape (drawing process). In the embodiment of the invention, it is assumed for the explanation that the droplet pattern is formed by jetting droplets of conductive pattern forming composition with an ink-jet type printer (not illustrated). A recording head comprising a plurality of nozzles which jet the conductive pattern forming composition is provided to the printer. The nozzles of the recording head has a nozzle diameter of 0.1 μm to 10 μm, which enable to form the conductive pattern 4 having line width of 20 μm or less. Since the particle size of the conductive fine particles in the conductive pattern forming composition is 0.1 nm or more and 20 nm or less, clogging is hard to be generated at the nozzles.

Subsequently the drawn droplet pattern is heated up to 60 to 450° C. for 1 to 60 minutes (heating process). By the heating, the conductive fine particles in the droplet pattern are fused with each other so that the droplet pattern becomes the conductive pattern 4. Here, the reason heating temperature is set at 60° C. or more is that organic substances is not evaporated or calcined sufficiently at less than 60° C., and the reason heating temperature is set at 450° C. or less is that the conductive pattern 4 is thermally damaged at more than 450° C. In addition, the heating process is preferably performed in vacuo or under inert gas atmosphere including hydrogen of 4% or less.

Subsequently the above photocurable resin is coated onto the foreside of the conductive pattern 4 (coating process), and light is irradiated to the coated photocurable resin (irradiation process). Since the photocurable resin is one comprising a photo polymerization initiator and photo polymerizable acrylic monomer or acrylic oligomer as main components, it is certainly cured by light so that the resin layer 2 is formed. Thus, the conductive pattern 4 is defiladed from oxygen.

According to the above-described manufacturing method of the circuit board 1, since the conductive pattern 4 can be defiladed from oxygen by the resin layer 2, it is possible to prevent the conductive pattern 4 from oxidation.

Further, since the photocurable resin coated on the foreside of the conductive pattern 4 can be certainly cured by light, it is possible to form the resin layer 2 on the conductive pattern 4 without the conductive pattern 4 oxidized.

By using the conductive pattern forming composition where micro conductive fine particles are dispersed by the dispersant without aggregation, it becomes possible to form the fine conductive pattern 4. Thus, implementing density of the conductive pattern 4 onto the base material 3 can be enhanced.

Further, since the conductive fine particles in the conductive pattern forming composition can be minimized in particle size, it is possible to provide conductivity to the droplet pattern by heating at comparatively low temperature, which are drawn with droplets of the conductive pattern forming composition on the surface of the base material 3.

In the above embodiment, it has been assumed for the explanation that the conductive fine particles is made of copper. However, it can be made of other metals such as gold, silver, ruthenium, rhodium, palladium, osmium, iridium, platinum, etc.

Also, it has been assumed for the explanation that the reduction is performed in an aqueous dispersing medium phase. However, it is possible to be performed in a emulsion of water and organic solvent.

Also, it has been assumed for the explanation that the formation of the conductive pattern 4 is performed by an ink-jet method. However other methods such as screen printing are available.

### Second Embodiment

In the first embodiment, the invention is explained by exemplifying the circuit board 1 comprising the base material 3, the conductive pattern 4 and the resin layer 2. In the second embodiment, the invention is explained by exemplifying the circuit board comprising a base material, a conductive pattern and a resin layer and further comprising a magnetic shielding layer. It is to be noted that the description which is as same as that of the first embodiment will be omitted in the following explanation, and the same reference numerals are used therein.

The circuit board 10 according to the second embodiment comprises a base material 3, and magnetic shielding layer 11 is laminated onto at least one surfade side of the base material 3.

The magnetic shielding layer 11 is formed by curing a sol-gel solution on the base material 3 by utilizing sol-gel method, in which the sol gel solution contains metal alkoxides of magnetic shielding metals having magnetic shielding property such as aluminum, magnesium, nickel, tin and the like as a metal base.

Here, the sol-gel method is described. The sol-gel method is one curing sol-gel solution by heating or light irradiation. Since the component of desired material is dissolved in a sol-gel solution in states of an ion or a molecule, it is expected that the desired compound will be obtained by the reaction, unless the desired material is consisted of a plurality of components. Therefore, it is possible that the solution includes several kinds of metals each having a function of shielding magnetic field. As a result, the sol-gel method has a property such that a plurality of metal alkoxides can be easily mixed and are subjected to condensation.

The material of the sol-gel solution used in the sol-gel method is a compound selected from organic metal compound such as metal alkoxide, organic salt, metal complex salt, metal complex and the like, and inorganic metal compound such as sulfate, nitrate and the like. The derivative of the metal alkoxide includes mono-, di- tri-and tetraalkoxide. The alkyl group of the metal alkoxide includes methyl, ethyl, propyl and the like.

The monomer components used in the sol-gel solution of the invention includes alkoxides of In, Sn, Zr, Zn, Si and the like. Alkoxide of In includes, for example, indium methoxyethoxide, indium isopropoxide, indium methyl(trimethyl) acetylacetonate and the like. Alkoxide of Sn includes, for example, tin methoxide, tin ethoxide, tin 2,4-pentandionate, tin tetra-n-butoxide and the like. Alkoxide of Zr includes zirconium ethoxide, zirconium methacryl oxyethyl acetoacetate tri-n-propoxide, zirconium n-propoxide, zirconium dimethacrylate dibuthoxide and the like. Alkoxide of Zn includes, for example, zinc N,N-dimethylaminoethoxide, zinc methoxyethoxide and the like. Alkoxide of Si includes, for example, tetramethoxysilane, tetraethoxysilane, methyltrimethoxysilane, dimethyldimethoxysilane, dimethyldibutoxysilane, trimethylmethoxysilane and the like.

Base monomer of the sol-gel solution is generally multivalent alkoxide, and furthermore, it may have a substituent being capable of photo polymerization. That is, the feature of resinification is a combination of polymerization by sol-gel reaction and photo polymerization. Representatives of the monomer includes, for example, vinylalkoxysilane, 3-(glycidoxy) propyltrimethoxysilane, acryloxysilane and the like.

The base monomer of the sol-gel solution comprises a functional group which binds covalently to dispersant components. Such functional group includes, for example, epoxy and isocyanate, and furthermore, blocking group of isocyanate.

A catalyst which promotes crosslinking reaction of condensation reaction in sol-gel reaction includes, for example;

1. lower alcohol such as water, methanol, etc,

2. acid such as hydrochloric acid, nitric acid, phosphoric acid, acetic acid, p-toluene sulfonic acid as examples,

3. metal catalyst such as Al chelate, Zr chelate, etc.

Here, chelating ligand includes salicylic acid, 1,3-diketone, hydroxycarboxylic acid, acetoacetate, etc.

In sol-gel reaction, it can be assumed that the sol-gel reaction is uniformly performed in anywhere when sol-gel solution as starting substance is transparent and uniform. The sol-solution of these compounds is prepared and is gelificated by hydrolysis or polycondensation reaction. Uniform organic-inorganic hybrid can be obtained in this method. This organic-inorganic hybrid is a binder composition having adhering function. The cured gel has flexibility and no micro pores of inorganic materials, and is toughened when organic materials are formed to be a hybrid. Also, heat resistance is improved by binding inorganic materials, which is especially useful in that droplet of nano composite metal is made to be shaped linier. Further, being different from pure inorganic material, the organic-inorganic hybrid contributes the improvement of adhesiveness with the base material 2 because stress relaxation easily takes place in organic-inorganic hybrid depending on contained organic materials.

As shown in FIG. 2, a conductive pattern 4 made up of conductive pattern forming composition is formed on an upper side of the magnetic shielding layer 11. When the line width of the conductive pattern 4 is less than 5 μm, sufficient electromagnetic wave shielding property is not obtained. When it is more than 50 μm, optical transparency is deteriorated in the electromagnetic shielding sheet having optical transparency. Therefore, it is configured to 5 μm to 10 μm.

The resin layer 2 which covers the conductive pattern 4 is provided on the conductive pattern.

Next, a method for manufacturing the circuit board 10 of the second embodiment is explained. First, the above sol-gel solution is coated onto at least one surface side of the film-shaped base material 3. Subsequently, the coated sol-gel solution is heated when it is heat curable solution, or light is irradiated to the sol-gel solution when it is photocurable solution. Thus, the sol-gel solution is cured to form the magnetic shielding layer 11 on the base material 3.

After the magnetic shielding layer 11 is formed on the base material 3 by curing the sol-gel solution, droplet pattern is drawn to be lattice shape of predetermined shape by jetting the conductive pattern forming composition onto the magnetic shielding layer 11 by ink-jet type printer (drawing process).

Subsequently the drawn droplet pattern is heated up to 60 to 450° C. for 1 to 60 minutes (heating process) After the conductive pattern 4 is formed, photocurable resin is coated onto the conductive pattern 4 to cover at least conductive pattern. Successively light is irradiated to the photocurable resin to cure and to form resin layer 2.

The magnetic shielding layer 11 is provided at least one of between the base material 3 and the conductive pattern 4, and on a surface plane where the conductive pattern 4 is formed. In the above manufacturing method, the explained case is that the conductive pattern 4 is formed on the magnetic shielding layer 11. However, it is possible that the conductive pattern is directly formed on the base material 3. In this case, electromagnetic wave shielding property can be obtained by providing the magnetic shielding layer 11 on a side where the conductive pattern 4 is not formed. When the conductive pattern 4 and the magnetic shielding layer 11 are respectively formed on either side of the base material, either the conductive pattern 4 or magnetic shielding layer 11 can be formed firstly. That is, as well as the above-described forming method where the magnetic shielding layer 11 is formed firstly, for example, another forming method can be given, that the conductive pattern 4 is formed onto the one side of the base material 3 firstly, subsequently heated to provide a conductivity, secondly the sol-gel solution is coated onto a side where the conductive pattern 4 is not formed and cured to form the magnetic shielding layer.

### EXAMPLES

Hereinafter, the present invention is explained in detail by referring the following examples. However the present invention is not limited thereto.

Performed in the example as stated below are synthesis of dispersant and manufacturing copper fine particles, manufacturing 2 types of conductive pattern forming compositions and forming a conductive pattern, and forming a resin layer. It is to be noted that values in parentheses designate proportion by weight, in the following description.

<<Synthesis of Dispersant>>Into a four-neck flask which was set in a warm bath of 75° C. under nitrogen atmosphere, isopropyl alcohol (100) as solvent, monomer components of dispersant and azoisobutyronitrile (1) was charged, and solution polymerization was performed. Used as the monomer components were methyl (meth)acrylate (30), stearyl (meth)acrylate (10), (meth)acrylate terminal methoxy adduct of ethylene oxide 20 and propylene oxide 5(30), (meth)acrylate terminal methoxy adduct of ethylene oxide 120 and butylene oxide 10 (20) and dimethylaminoethyl (meth)acrylate (10).

Azoisobutyronitrile (0.5) was further added 3 hours after initiation of the polymerization.

Further after another 3 hours, azoisobutyronitrile (0.5) and laurylthio Kalcol (10) were added and solution polymerization is performed for 2 hours.

Weight mean molecular weight of the synthesized dispersant was measured by gel permeation chromatography (GPC). As the columns of GPC apparatus, TKS gel Super 1000, TSK gel Super 2000 and TSK gel Super 3000 (by Tosoh Co., Ltd.) were used, and the weight mean molecular weight was determined from differential refractive index. In the measurement, tetrahydrofuran (THF) was used as the carrier.

Measured weight mean molecular weight was 35000.

<<Manufacture of Copper Fine Particles>>Copper nitrate (50) was dissolved into purified water (300) with stirring.

Subsequently, the dispersant synthesized as described above (10) was added into the solution, and dissolved to be uniform.

Subsequently monoethanolamine (30) was gradually added to the solution over 30 minutes with stirring so as to reduce the copper ion to form the copper fine particles. pH value of the aqueous dispersing medium phase was adjusted to 8.5. The aqueous dispersing medium phase was kept at 50° C. with stirring for following 2 hours.

Subsequently, ethyl acetate (100) was added to the aqueous dispersing medium as organic dispersing medium, and the solution was mixed with ultrasonic mixer for 10 minutes. Thus the aqueous dispersing medium and the organic dispersing medium are to be a microemulsion.

Subsequently temperature of the above microemulsion was raised up to 60° C. over 20 minutes with stirring.

Subsequently the stirring was stopped and the microemulsion was left at rest to separate the microemulsion into two phases of aqueous dispersing medium phase and organic dispersing medium phase where the copper fine particles are dispersed.

Subsequently the organic dispersing medium phase was collected and washed with purified water (300) for 2 times to obtain copper fine particles dispersing solution having mean particle size of 8 nm.

<<Manufacture of Conductive Pattern Forming Composition and Formation of Conductive Pattern (1)>>

The organic dispersing medium obtained as described above was evaporated and exsiccated.

Subsequently the exsiccated organic dispersing medium was mixed with resin components and curing agent and extruded with three roll mill to prepare the conductive pattern forming composition. For more details, used as the resin components are epoxy resin of bisphenol A type (Epicoat828, by Japan Epoxy Resin Co., Ltd.) and epoxy resin where dimer acid is esterified with glycidyl group (YD-171, by Tohto chemical Co., Ltd.)(hereinafter referred to as epoxy resin derived from dimer acid). Used as the curing agent was an amine adduct type curing agent (MY-24, by Ajinomoto Co., Ltd.). In the above mixture, each proportion of the evaporated organic dispersing medium, bisphenol A type epoxy resin, epoxy resin derived from dimer acid and amin adduct type curing agent is 85 weight % 3 weight %, 9 weight % and 3 weight % respectively.

Subsequently the above conductive pattern forming composition was printed onto a glass epoxy base material by screen printing, and was thermoset by heating at 150° C. in an oven.

The formed conductive pattern has line width of 30 μnm and fine conductivity of relative resistance of 7×10⁻⁵Ω·cm.

<<Manufacture of Conductive Pattern Forming Composition and Formation of Conductive Pattern (2)>>

The organic dispersing medium obtained as described above is evaporated and exsiccated.

Subsequently the exsiccated organic dispersing medium was mixed with isopropyl alcohol to prepare the conductive pattern forming composition. The content of the above exsiccated dispersing medium in the mixture was adjusted to 25 weight %.

The above conductive pattern forming composition was printed by ink-jet printing onto a glass epoxy base material, and was thermoset by heating at 150° C. for 20 minutes in an oven.

The formed conductive pattern has line width of 10 μm and fine conductivity of relative resistance of 8×10⁻⁵Ω·cm.

<<Formation of Resin Layer>>

A photocurable resin was coated onto the baseboard where the above conductive pattern had been formed, and was cured by ultraviolet irradiation. Used as the photo polymerization initiator in the photocurable resin are benzophenon (1) and Michler's ketone (1). Used as the photo polymerizable acrylic monomer are 2-hydroxypropylacrylate (15), 1,4-butadiol diacrylate (35), trimethyrolpropanetriacrylate (15) and hydroxypivalate neopencylglycoldiacrylate (35).

<<Manufacture of Magnetic Shielding Material>>

Into a four-neck flask, isopropyl alcohol (100) and acetyl acetone (200) as solvent, and indium trimethoxide (15), tin tetraethoxide (30) and diethoxymethylsilane (40), and paratoluenesulfonic acid (0.5) as catalyst were charged and condensation reaction was performed at 30° C. over 5 hours. Since reaction rate of acetylacetone is extremely rapid expect condensation reaction of silane, it was used to control the condensation reaction rate. Successively dimethoxysilanediacrylate (5) and 3-glycidoxypropyltrimethoxysilane (10) were added and the condensation reaction was further performed at 30° C. over 3 hours. The obtained sol-gel solution was coated onto a triacetate film as base material, and heated at 120° C. for 5 minutes to be cured.

What is claimed is:

1. A circuit board comprising a base material, a conductive pattern which is formed on the base material, and a resin layer which is formed on the conductive pattern by a photocurable resin.

2. The circuit board of claim 1, wherein the photocurable resin comprises a photo polymerization initiator and a photocurable acrylic type monomer or a photocurable acrylic type oligomer as main components.

3. The circuit board of claim 1, wherein a line width of the conductive pattern is 20 μm or less.

4. The circuit board of claim 1, further comprising a magnetic shielding layer provided at least one of between the base material and the conductive pattern, and on a surface plane where the conductive pattern is not formed in the base material.

5. A manufacturing method of a circuit board, comprising;
drawing a droplet pattern with droplets of a conductive pattern forming composition on a surface of a base material,
heating the drawn droplet pattern so as to convert the droplet pattern into a conductive pattern,
coating a photocurable resin onto the conductive pattern after the heating, and
irradiating light to cure the coated photocurable resin after the coating.

6. The method of claim 5, wherein the drawing comprises drawing the droplet pattern by jetting droplets of the conductive pattern forming composition in an ink-jet method.

7. The method of claim 5, wherein the drawing comprises jetting the conductive pattern forming composition from a nozzle having a nozzle diameter of 0.1 μm to 10 μm.

8. The method of claim 5, wherein the drawing comprises drawing the droplet pattern having line width of 20 μm or less.

9. The method of claim 5, wherein the conductive pattern forming composition comprises conductive fine particles having at least one kind of metal, and a dispersant which disperses the conductive pattern fine particles, and
wherein the dispersant comprises a polymer in which a main chain of the polymer comprises tertiary amine type monomer and a side chain of the polymer comprises polyether type anionic monomer.

10. The method of claim 5, wherein a sol-gel solution for forming a magnetic shielding layer is coated onto at least one surface of the base material and is cured to be the magnetic shielding layer, and subsequently the drawing is performed onto at least one of a surface of the magnetic shielding layer and a surface of the base material.

11. The method of claim 5, wherein a sol-gel solution for forming a magnetic shielding layer is coated onto a reverse side of a surface where the conductive pattern is formed by the heating in the base material, and is cured to form the magnetic shielding layer.
